(19) United States
(12) Patent Application Publication
(10) Pub. No.: US 2023/0223351 A1
(43) Pub. Date: Jul. 13, 2023

(54) DISPLAY DEVICE

(71) Applicant: Samsung Display Co., LTD., Yongin-si (KR)

(72) Inventors: KYUNG-MOK LEE, Seoul (KR); HYUNWOO LEE, Seongnam-si (KR); DONG-YOUB LEE, Cheonan-si (KR); Young Min CHO, Seongnam-si (KR)

(21) Appl. No.: 18/082,538

(22) Filed: Dec. 15, 2022

(30) Foreign Application Priority Data
Jan. 11, 2022 (KR) 10-2022-0003953

(51) Int. Cl. H01L 23/544

(52) U.S. Cl. CPC H01L 23/544; H01L 2223/54426

(57) ABSTRACT

A display device includes a display panel including a non-display area in which a panel pad is disposed, and a pad portion which contacts the non-display area of the display panel, where the pad portion includes an alignment mark overlapping the panel pad, the panel pad includes a first vertical portion and a second vertical portion spaced apart from each other in a first direction, a first horizontal portion connected to the first vertical portion, and a second horizontal portion connected to the second vertical portion, and the first horizontal portion and the second horizontal portion are spaced apart from each other in a second direction crossing the first direction.

This application claims priority to Korean Patent Application No. 10-2022-0003953, filed on Jan. 11, 2022, and all the benefits accruing therefrom under 35 U.S.C. § 119, the content of which in its entirety is herein incorporated by reference.

### BACKGROUND

### (a) Field

The disclosure relates to a display device, and more particularly, to a display device having a reduced alignment error.

### (b) Description of the Related Art

A display device includes a display panel including pixels for displaying an image. In addition to the pixels, the display panel may further include circuits, a pad for inputting signals used to control the pixels and circuits, and a signal line connected to the pad to transfer the signals.

The pad may be formed by a separate process and then attached to the display panel to apply an external signal to the display panel.

### SUMMARY

Embodiments provide a display device capable of accurately measuring alignment between a display panel and a pad portion.

An embodiment of the invention provides a display device including a display panel including a non-display area in which a panel pad is disposed, and a pad portion which contacts the non-display area of the display panel, where the pad portion includes an alignment mark overlapping the panel pad, the panel pad includes a first vertical portion and a second vertical portion spaced apart from each other in a first direction, a first horizontal portion connected to the first vertical portion, and a second horizontal portion connected to the second vertical portion, and the first horizontal portion and the second horizontal portion are spaced apart from each other in a second direction crossing the first direction.

In an embodiment, a distance between the first vertical portion and the second vertical portion in the first direction may be equal to or longer than a length of the alignment mark in the first direction.

In an embodiment, a distance between the first horizontal portion and the second horizontal portion in the second direction may be equal to or shorter than a length of the alignment mark in the second direction.

In an embodiment, the first horizontal portion and the second horizontal portion may extend from the first vertical portion and the second vertical portion, respectively, in a direction away from the alignment mark.

In an embodiment, the first horizontal portion and the second horizontal portion may extend from the first vertical portion and the second vertical portion, respectively, in a direction closer to the alignment mark.

In an embodiment, at least one selected from the first vertical portion and the second vertical portion may include parts spaced apart from each other in the first direction.

In an embodiment, the first vertical portion may be connected to a part of the first horizontal portion other than an end part of the first horizontal portion.

In an embodiment, a corner of the alignment mark corresponding to the first horizontal portion of the panel pad may include a portion which does not overlap the first horizontal portion of the panel pad.

In an embodiment, the panel pad may not be connected to a wire disposed in the display panel.

In an embodiment, an angle between the first vertical portion and the first horizontal portion may be less than 90 degrees.

In an embodiment, the display device may further include a third horizontal portion connected between the first vertical portion and the second vertical portion.

Another embodiment of the invention provides a display device including: a display panel including a non-display area in which a panel pad is disposed, and a pad portion which contacts the non-display area of the display panel, where the pad portion includes an alignment mark overlapping the panel pad, the panel pad includes a first vertical portion and a second vertical portion spaced apart from each other in a first direction.

In an embodiment, the display device may further include a first horizontal portion positioned between the first vertical portion and the second vertical portion, and the first horizontal portion may not be connected to at least one selected from the first vertical portion and the second vertical portion.

In an embodiment, the display device may further include a second horizontal portion connected to the first vertical portion, and the second horizontal portion may not be connected to the second vertical portion.

In an embodiment, the second horizontal portion may extend from the first vertical portion in a direction closer to the alignment mark.

In an embodiment, The second horizontal portion may extend from the first vertical portion in a direction away from the alignment mark.

In an embodiment, the first vertical portion may be connected to a part of the second horizontal portion other than an end part of the second horizontal portion.

In an embodiment, at least one selected from the first vertical portion and the second vertical portion may include parts which are spaced apart from each other in a second direction crossing the first direction.

In an embodiment, the display device may further include a third horizontal portion connected between the first vertical portion and the second vertical portion.

In an embodiment, an angle between the first vertical portion and a horizontal side of the alignment mark may be less than 90 degrees.

According to embodiments, alignment between a display panel and a pad portion of a display device may be accurately measured.

### BRIEF DESCRIPTION OF THE DRAWINGS

FIG. 1 schematically illustrates a configuration of a pad portion according to an embodiment.

FIG. 2 schematically illustrates a configuration of a non-display area of a display panel according to an embodiment.

FIG. 3 schematically illustrates a configuration in which a pad of FIG. 1 is attached to a display device of FIG. 2.

FIG. 4 to FIG. 6 illustrate a configuration for checking alignment through an alignment mark and a panel pad in a display device according to an embodiment.

FIG. 7 to FIG. 9 illustrate distance measurement when a panel pad and an alignment mark overlap each other.

FIG. 10 illustrates a measurement result obtained while varying a distance between an alignment mark and a panel pad.

FIG. 11 to FIG. 30 illustrate panel pads according to various embodiments.

### DETAILED DESCRIPTION

The invention will be described more fully hereinafter with reference to the accompanying drawings, in which various embodiments of the invention are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

To clearly describe the invention, parts that are irrelevant to the description are omitted, and like reference numerals refer to like elements throughout.

Further, since sizes and thicknesses of constituent members shown in the accompanying drawings are arbitrarily given for better understanding and ease of description, the invention is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Further, in the specification, the phrase “in a plan view” means when an object portion is viewed from above, and the phrase “in a cross-sectional view” means when a cross-section taken by vertically cutting an object portion is viewed from the side.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

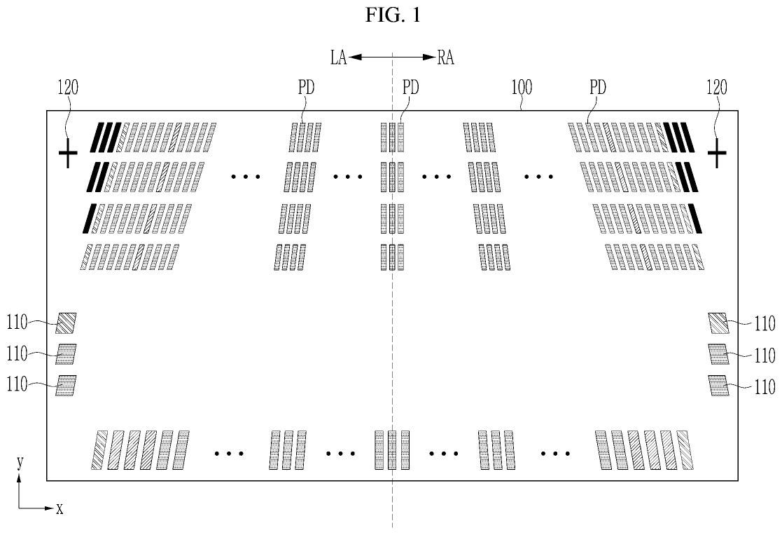

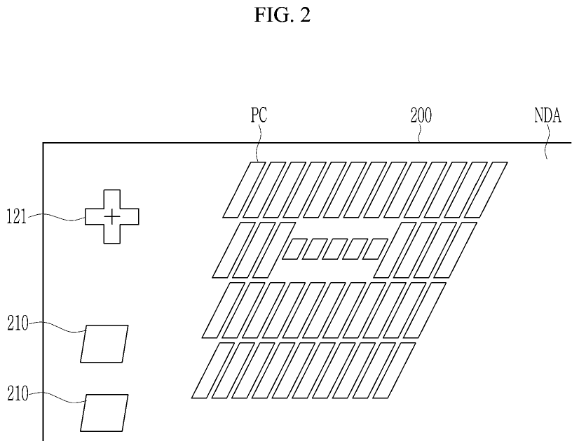

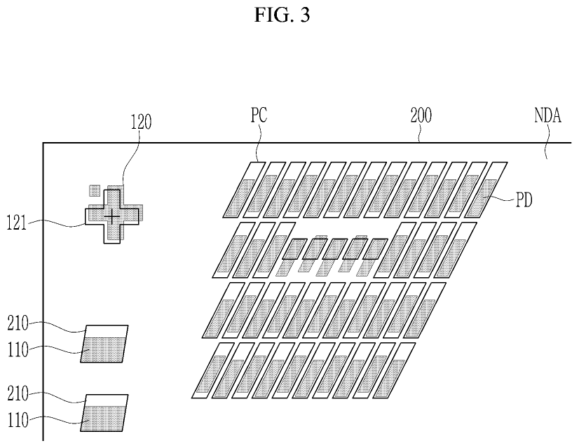

FIG. 1 schematically illustrates a configuration of a pad portion 100 according to an embodiment. FIG. 2 schematically illustrates a configuration of a non-display area NDA of a display panel 200 according to an embodiment. FIG. 3 schematically illustrates a configuration in which a pad of FIG. 1 is attached to a display device of FIG. 2.

Referring to FIG. 1, in an embodiment, a plurality of pads PD are positioned on a pad portion 100. Each of the pads PD may be positioned to have a symmetrical structure inclined toward a center of the pad portion 100. In an embodiment, as illustrated in FIG. 1, the pad PD positioned at a left side LA of the pad portion 100 is inclined in a right direction toward the center, and the pad PD positioned at a right side RA of the pad portion 100 is inclined in a left direction toward the center. As illustrated in FIG. 1, the pad PD positioned at the left side LA of the pad portion 100 may have a shape of a parallelogram that is inclined in the right direction toward the center, and the pad PD positioned at the right side RA of the pad portion 100 may have a shape of a parallelogram that is inclined in the left direction toward the center.

In such an embodiment, where the pad PD has a shape inclined toward the center, a contact area between the pad PD of the pad portion 100 and a pad contact portion PC of the display panel 200 may be maintained through a movement in a y-axis direction even when the pad portion 100 and the display panel 200 are not effectively aligned in an x-axis direction. Accordingly, in such an embodiment, the pad portion 100 and the display panel 200 may be stably connected.

A cross alignment mark 120 and an alignment mark 110 may be positioned on a side surface of the pad portion 100. These alignment marks may be positioned at an edge of the pad portion 100.

The cross alignment mark 120 may have a cross shape. The alignment mark 110 may have a quadrangular shape, for example, may have a shape of a parallelogram that is inclined in one direction.

In an embodiment, the alignment mark 110 may overlap the panel pad 210 of the display panel 200 to check alignment between the display panel 200 and the pad portion 100. Embodiments of the invention relate to a shape of the panel pad 210 of the display panel 200 overlapping the alignment mark 110 of the pad portion 100, and the shape of the panel pad 210 according to embodiments will be described later in detail.

FIG. 2 illustrates a portion of an embodiment of the display panel 200. FIG. 2 illustrates the non-display area NDA of the display panel 200. Although not illustrated, the display panel 200 may include a display area in which pixels are positioned and an image is displayed. The non-display area NDA may be positioned to surround a periphery of the display area.

Referring to FIG. 2, the non-display area NDA of the display panel 200 includes a plurality of pad contact portions PC. In an embodiment, a shape and arrangement of the pad contact portions PC may be the same as those of the pads PD of FIG. 1. In such an embodiment, the pad contact portion PC positioned at a left side LA may have a shape of a parallelogram that is inclined in the right direction toward the center, and the pad contact portion PC positioned at a right side may have a shape of a parallelogram that is inclined in the left direction toward the center. In FIG. 2, for convenience of illustration, only a left portion of the display panel 200 is illustrated, and the pad contact portion PC has a shape of a parallelogram that is inclined in the right direction toward the center.

The display panel 200 of FIG. 2 includes a cross alignment mark contact portion 121 corresponding to the cross alignment mark 120 of the pad portion 100 of FIG. 1, and a panel pad 210 corresponding to the alignment mark 110 of the pad portion 100.

In an embodiment, when the display panel 200 and the pad portion 100 come into contact with each other, an alignment degree between the display panel 200 and the pad portion 100 may be checked by measuring an alignment degree between the cross alignment mark 120 of the pad portion 100 and the cross alignment mark contact portion 121 of the display panel 200. In such an embodiment, the alignment degree between the display panel 200 and the pad portion 100 may be checked by measuring the alignment between the alignment mark 110 of the pad portion 100 and the panel pad 210 of the display panel 200. In an embodiment, the alignment mark 110 may check alignment between the display panel 200 and the pad portion 100 in the y-axis direction.

FIG. 3 illustrates a configuration in which the display panel 200 and the pad portion 100 are in contact with each other. Referring to FIG. 3, the pad PD and the pad contact portion PC overlap each other, the cross alignment mark 120 and the cross alignment mark contact portion 121 overlap each other, and the alignment mark 110 and the panel pad 210 overlap each other. In such an embodiment, as the pad PB and the pad contact portion PC come into contact with each other, a signal from the pad PD is transferred to the display panel 200.

The alignment between the display panel 200 and the pad portion 100 may be checked through the cross alignment mark 120, the cross alignment mark contact portion 121, the alignment mark 110, and the panel pad 210.

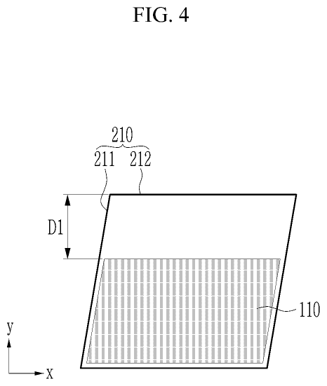

FIG. 4 to FIG. 6 illustrate a configuration for checking alignment through the alignment mark 110 and the panel pad 210 in a display device according to an embodiment. Referring to FIG. 4, the alignment between the display panel 200 and the pad portion 100 in the y-axis direction may be checked by measuring a distance D1 between an upper horizontal portion 212 of the panel pad 210 and the alignment mark 110 or a distance D1 from the upper horizontal portion 212 of the panel pad 210 to the alignment mark 110.

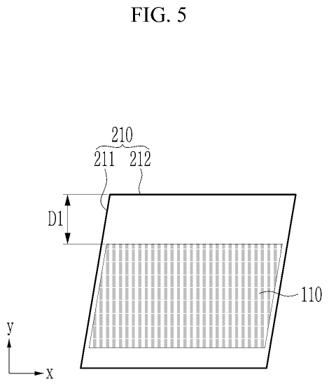

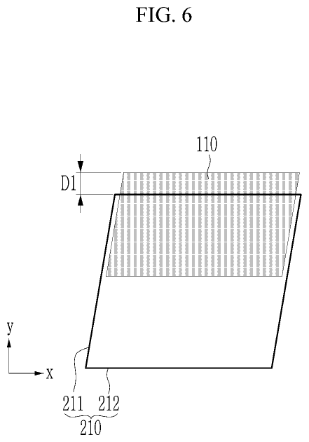

In the case of FIG. 5, the distance D1 may be about −10 micrometers (μm). This indicates that misalignment between the display panel 200 and the pad portion 100 occurs by about 10 μm in the y-axis direction. In addition, in the case of FIG. 6, the distance D1 may be about +5 μm. This indicates that misalignment between the display panel 200 and the pad portion 100 occurs by about 5 μm in the y-axis direction. In this case, misalignment directions in FIG. 5 and FIG. 6 may be opposite to each other. That is, the misalignment occurs in a downward direction of an y-axis (in the alignment state shown in FIG. 5, while the misalignment may occur in an upward direction of the y-axis in the alignment state shown in FIG. 6.

In FIG. 4 to FIG. 6, the panel pad 210 may have a quadrangular ring shape. In an embodiment, the panel pad 210 includes two vertical portions 211 and two horizontal portions 212, and all of the vertical portions 211 and the horizontal portions 212 may be connected to each other. In an embodiment, as shown in FIG. 4 to FIG. 6, the panel pad 210 may have a shape of a parallelogram ring that is inclined in one direction. That is, an angle (e.g., a smaller one of angles) between the vertical portions 211 and the horizontal portions 212 of the panel pad 210 may be less than 90 degrees.

In an embodiment, as shown in FIG. 4 to FIG. 6, where the panel pad 210 has a closed quadrangular shape, a measurement error may occur in an overlapping area of the panel pad 210 and the alignment mark 110. Hereinafter, a case in which the measurement error occurs will be described.

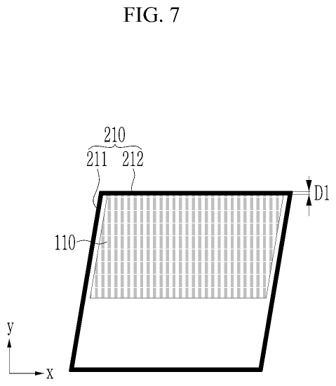

FIG. 7 to FIG. 9 illustrate distance measurement when the panel pad 210 and the alignment mark 110 overlap each other. In FIG. 7, the panel pad 210 and the alignment mark 110 may not overlap each other. In this case, a distance D1 between an upper end of the panel pad 210 and an upper end of the alignment mark 110 is illustrated in FIG. 7.

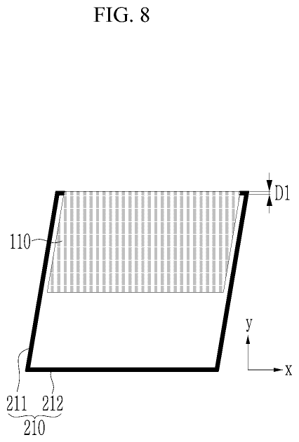

In FIG. 8, the panel pad 210 and the alignment mark 110 partially overlap each other. Accordingly, as compared with the case shown in FIG. 7, the alignment mark 110 is positioned above the panel pad 210 in the y-axis direction compared with in FIG. 7. However, even in the case of FIG. 8, the distance D1 between the upper end of the panel pad 210 and the upper end of the alignment mark 110 is measured in a same manner as in FIG. 7. This is because the uppermost end of the alignment mark 110 overlaps and is covered with the panel pad 210, and thus a portion of the alignment mark 110 that does not overlap the panel pad 210 is visually recognized as an uppermost end thereof. Since alignment measurement of the alignment mark 110 and the panel pad 210 is performed on a rear surface of the display panel 200, an actual uppermost end of the alignment mark 110 covered by the panel pad 210 may not be effectively checked.

Accordingly, although actual positions of the alignment marks 110 in FIG. 7 and FIG. 8 are different from each other, the distance D1 between the upper end of the panel pad 210 and the upper end of the alignment mark 110 is equally measured, and thus the measurement error may occur.

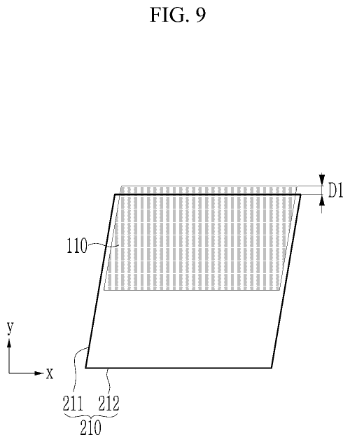

In FIG. 9, the uppermost end of the alignment mark 110 does not overlap the panel pad 210. As a result, the distance D1 between the uppermost end of the alignment mark 110 and the uppermost end of the panel pad 210 is accurately measured again.

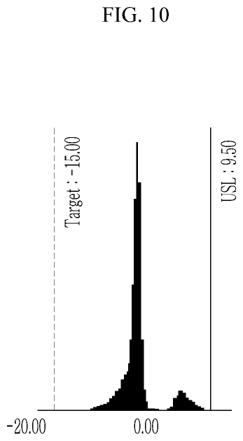

FIG. 10 illustrates a measurement result obtained while varying the distance between the alignment mark 110 and the pad portion 100. Referring to FIG. 10, there is a section in which data is empty without following a normal distribution in a region where the alignment mark 110 and the panel pad 210 overlap (a section in which the distance is 0) each other. This section corresponds to a portion where the alignment mark 110 and the panel pad 210 overlap each other as illustrated in FIG. 8. Accordingly, a measurement error section may occur as in FIG. 10, which is not desirable for process management.

Accordingly, in embodiments of the display device according to the invention, the horizontal portion 212 of the uppermost end of the panel pad 210 was partially or entirely removed to prevent such a measurement error section from occurring. Therefore, in such embodiments, consistency may be improved during the process.

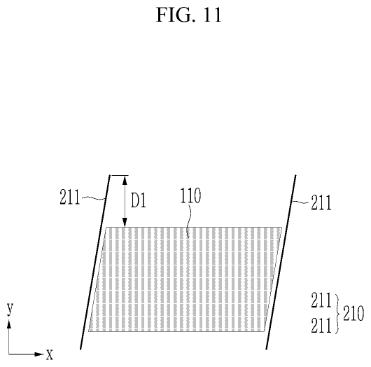

FIG. 11 illustrates the alignment mark 110 and the panel pad 210 according to an embodiment. Referring to FIG. 11, an embodiment of the panel pad 210 may not have a closed ring shape, but may have a quadrangular shape with a horizontal portion removed. In such an embodiment, as illustrated in FIG. 11, the panel pad 210 includes two vertical portions 211 obliquely positioned and does not include a horizontal portion.

Accordingly, when misalignment of the alignment mark 110 in the y-axis direction, the alignment mark 110 does not overlap the panel pad 210. As a result, the measurement error section which is created when measuring the distance between the alignment mark 110 and the panel pad 210 may be effectively prevented from occurring.

In an embodiment of FIG. 11, the distance D1 between the alignment mark 110 and the panel pad 210 may be measured as a distance between an uppermost end of the vertical portion 211 of the panel pad 210 and an uppermost end of the alignment mark 110. In such an embodiment, since the panel pad 210 does not include a horizontal portion, even when the alignment mark 110 and the panel pad 210 are misaligned in the y-axis direction, the alignment mark 110 and the panel pad 210 do not overlap each other.

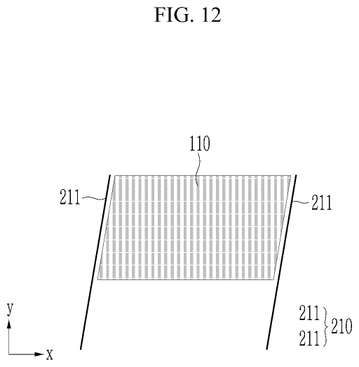

FIG. 12 illustrates a configuration in which the alignment mark 110 and the panel pad 210 do not overlap each other. In the case where the alignment mark 110 is positioned as illustrated in FIG. 12, if the panel pad 210 has the same shape as in FIG. 4 to FIG. 9, the horizontal portion 212 of the uppermost end of the alignment mark 110 may be covered by the panel pad 210 as illustrated in FIG. 8. In this case, the distance between the alignment mark 110 and the panel pad 210 may not be accurately measured, such that the alignment between the display panel 200 and the pad portion 100 may not be accurately measured. In an embodiment of the invention, as illustrated in FIG. 11, the upper and lower horizontal portions of the panel pad 210 are removed, and thus the uppermost end of the alignment mark 110 may not be covered by the panel pad 210, and a distance between the alignment mark 110 and the panel pad 210 may be accurately measured.

In the embodiments of FIG. 11 and FIG. 12, an area of the vertical portion 211 of the panel pad 210, which is a reference for measuring the distance between the alignment mark 110 and the panel pad 210, is narrow, and thus a distance measurement between the alignment mark 110 and the panel pad 210 may not be easily performed.

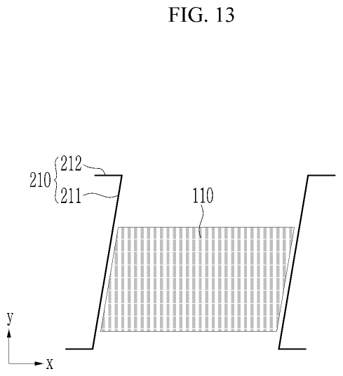

FIG. 13 to FIG. 16 illustrate the alignment mark 110 and the panel pad 210 according to alternative embodiments. Referring to FIG. 13, an embodiment of the panel pad 210 includes the horizontal portion 212 extending outward from the vertical portion 211. In the following specification, a direction toward the alignment mark 110 is referred to as an inner direction, and a direction away from the alignment mark 110 is referred to as an outer direction.

The horizontal portion 212 is formed in the vertical portion 211 in an opposite direction in which the alignment mark 110 is not positioned. In an embodiment, as described above with reference to FIG. 4 to FIG. 9, the horizontal portion 212 may be formed to connect the vertical portions 211 positioned side by side with each other. In an alternative embodiment, as shown in FIG. 13, the horizontal portion 212 does not connect the adjacent vertical portions 211 and is positioned outward.

In such an embodiment, as illustrated in FIG. 13, the horizontal portion 212 is not formed in a portion overlapping the uppermost end of the alignment mark 110. Accordingly, the uppermost end of the alignment mark 110 may not be covered by the panel pad 210, and a distance between the alignment mark 110 and the panel pad 210 may be accurately measured. In an embodiment of FIG. 13, the horizontal portion 212 having a predetermined distance outward is provided, such that the distance between the alignment mark 110 and the panel pad 210 may be easily measured.

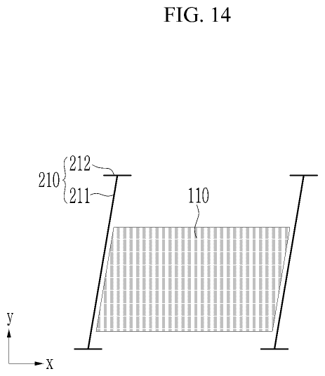

An embodiment of FIG. 14 is substantially the same as the embodiment of FIG. 13 except that a position of the horizontal portion 212 is slightly different from that of FIG. 13. Accordingly, any repetitive detailed description of same constituent elements will be omitted. Referring to FIG. 14, in an embodiment, a portion of the horizontal portion 212 is positioned at a right side with respect to the vertical portion 211, and a portion thereof is positioned at a left side with respect to the vertical portion 211. In such an embodiment, the vertical portion 211 is connected to a part other than an end part of the horizontal portion 212.

In the case of the embodiment of FIG. 14, a portion of the horizontal portion 212 may overlap the alignment mark 110, but since there is a non-overlapping area, the distance between the alignment mark 110 and the panel pad 210 may be accurately measured.

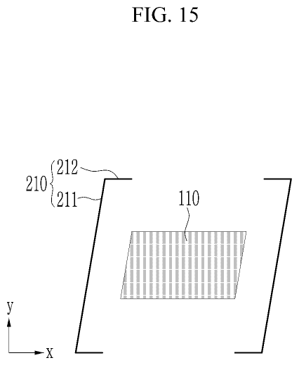

FIG. 15 illustrates the alignment mark 110 and the panel pad 210 according to another alternative embodiment. Referring to FIG. 15, in the panel pad 210 according to an embodiment, two vertical portions 211 are spaced apart from each other by a width that is greater than a horizontal width of the alignment mark 110, and the horizontal portion 212 is positioned in the vertical portion 211 in a direction toward the facing vertical portion 211. In such an embodiment, a distance between the two horizontal portions 212 may be greater than the horizontal width of the alignment mark 110. Accordingly, the uppermost end of the alignment mark 110 may not be covered by the panel pad 210, and a distance between the alignment mark 110 and the panel pad 210 may be accurately measured.

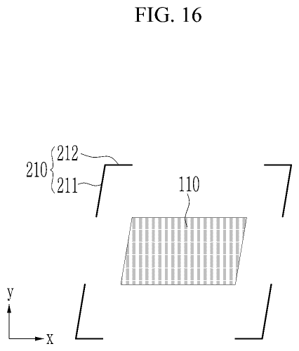

An embodiment of FIG. 16 is substantially the same as the embodiment of FIG. 15 except that a portion of the vertical portion 211 is removed. Accordingly, any repetitive detailed description of same constituent elements will be omitted. In an embodiment of FIG. 16, the uppermost end of the alignment mark 110 may not be covered by the panel pad 210, and a distance between the alignment mark 110 and the panel pad 210 may be accurately measured.

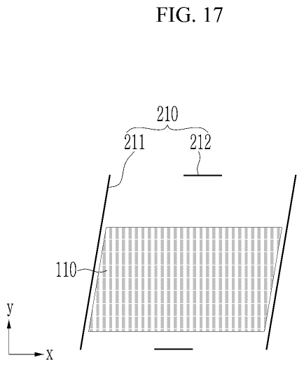

FIG. 17 illustrates the alignment mark 110 and the panel pad 210 according to another alternative embodiment. Referring to FIG. 17, the panel pad 210 according to an embodiment includes a vertical portion 211 and a horizontal portion 212 not connected to the vertical portion 211. The horizontal portion 212 may be positioned to have a length that is shorter than the horizontal width of the alignment mark 110. In the case of the embodiment of FIG. 17, a portion of the horizontal portion 212 may overlap the alignment mark 110, but since there is a non-overlapping area, the distance between the alignment mark 110 and the panel pad 210 may be accurately measured.

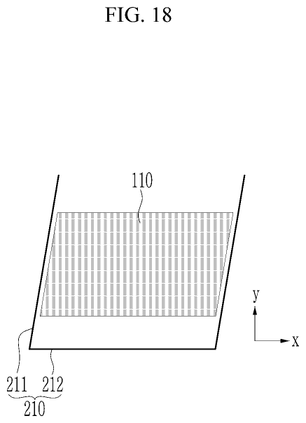

An embodiment of FIG. 18 is substantially the same as the embodiment of FIG. 11, except that the panel pad 210 further includes a horizontal portion 212 positioned at a lower end of the panel pad 210 than in the embodiment of FIG. 11. Accordingly, any repetitive detailed description of same constituent elements will be omitted. Referring to FIG. 18, alignment is checked by measuring a distance between an uppermost end of the alignment mark 110 and the panel pad 210, and thus even when the horizontal portion 212 is positioned at a lower end, distance measurement is not affected. Accordingly, the distance between the alignment mark 110 and the panel pad 210 may be accurately measured.

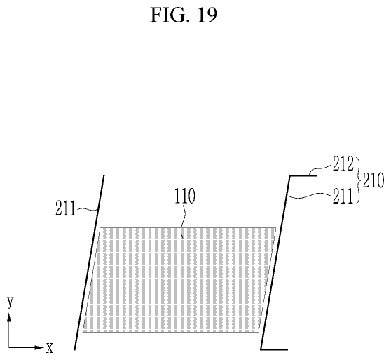

FIG. 19 to FIG. 21 illustrate the alignment mark 110 and the panel pad 210 according to other alternative embodiments.

Referring to FIG. 19, the panel pad 210 according to an embodiment is substantially the same as in the embodiment of FIG. 13 except that the panel pad 210 further includes one vertical portion 211 not connected to the horizontal portion 212 and one vertical portion 211 connected to the horizontal portion 212. Accordingly, any repetitive detailed description of same constituent elements will be omitted.

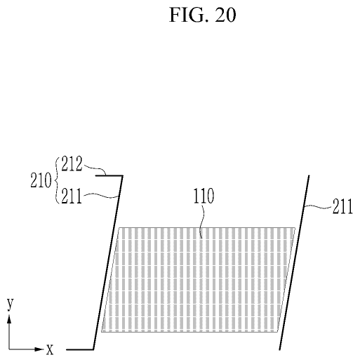

FIG. 19 illustrates a configuration in which a left side of the panel pad 210 is a vertical portion 211 not connected to the horizontal portion 212, but alternatively, as illustrated in FIG. 20, a right side of the panel pad 210 may be the vertical portion 211 not connected to the horizontal portion 212.

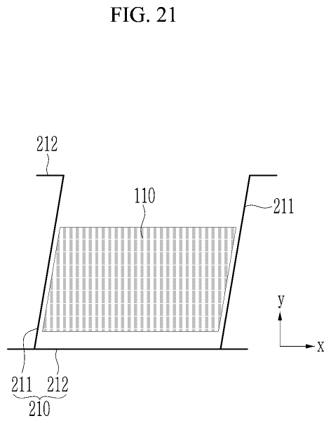

An embodiment of FIG. 21 is substantially the same as the embodiment of FIG. 13, except that the panel pad 210 further includes a horizontal portion 212 positioned at a lower end of the panel pad 210 and connected between the vertical portions 211. Accordingly, any repetitive detailed description of same constituent elements will be omitted.

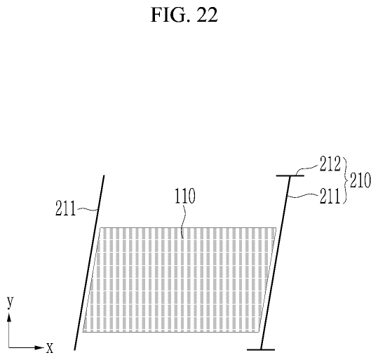

FIG. 22 to FIG. 24 illustrate the alignment mark 110 and the panel pad 210 according to other alternative embodiments.

Referring to FIG. 22, the panel pad 210 according to an embodiment is substantially the same as the embodiment of FIG. 14 except that the panel pad 210 further includes one vertical portion 211 not connected to the horizontal portion 212 and one vertical portion 211 connected to the horizontal portion 212. Accordingly, any repetitive detailed description of same constituent elements will be omitted.

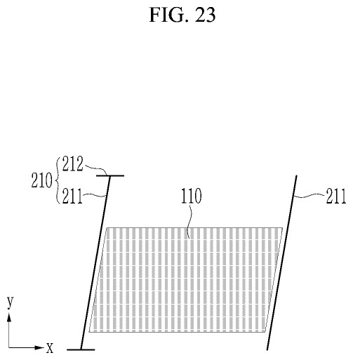

FIG. 22 illustrates a configuration in which a left side of the panel pad 210 is a vertical portion 211 not connected to the horizontal portion 212, but alternatively, as illustrated in FIG. 23, a right side of the panel pad 210 may be the vertical portion 211 not connected to the horizontal portion 212.

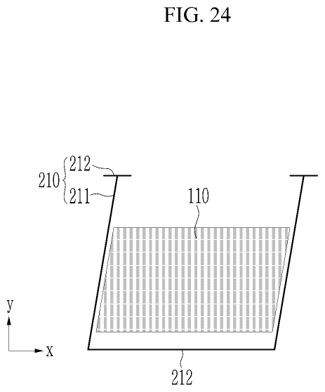

An embodiment of FIG. 24 is substantially the same as the embodiment of FIG. 14, except the panel pad 210 it further includes a horizontal portion 212 positioned at a lower end of the panel pad 210 and connected between the vertical portions 211. Accordingly, any repetitive detailed description of the same constituent elements will be omitted.

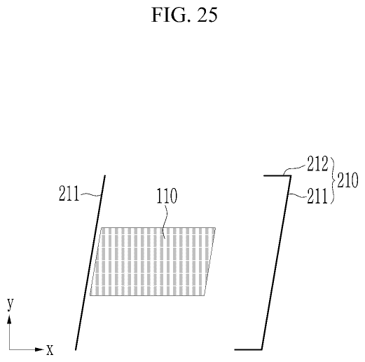

FIG. 25 to FIG. 27 illustrate the alignment mark 110 and the panel pad 210 according to other alternative embodiments.

Referring to FIG. 25, the panel pad 210 according to an embodiment is substantially the same as the embodiment of FIG. 15 except that the panel pad 210 further includes one vertical portion 211 not connected to the horizontal portion 212 and one vertical portion 211 connected to the horizontal portion 212. A detailed description of same constituent elements will be omitted.

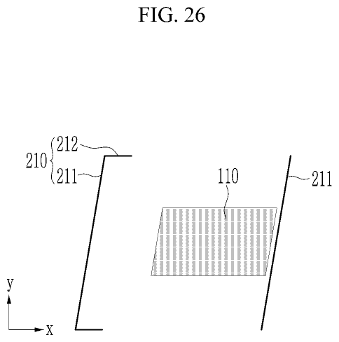

FIG. 25 illustrates a configuration in which a left side of the panel pad 210 is a vertical portion 211 not connected to the horizontal portion 212, but alternatively, as illustrated in FIG. 26, a right side of the panel pad 210 may be the vertical portion 211 not connected to the horizontal portion 212.

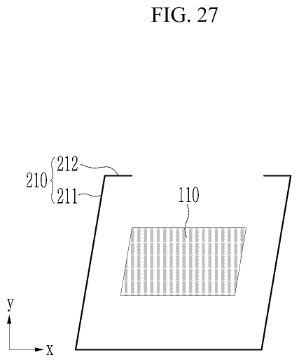

An embodiment of FIG. 27 is substantially the same as the embodiment of FIG. 15, except that the panel pad 210 further includes a horizontal portion 212 positioned at a lower end of the panel pad 210 and connected between the vertical portions 211. Accordingly, any repetitive detailed description of same constituent elements will be omitted.

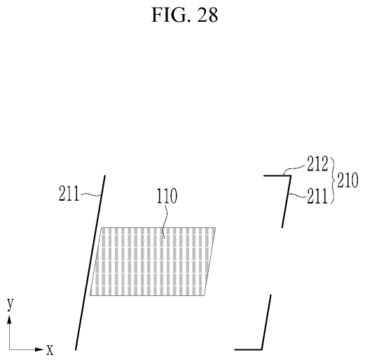

FIG. 28 to FIG. 30 illustrate the alignment mark 110 and the panel pad 210 according to other alternative embodiments.

Referring to FIG. 28, the panel pad 210 according to an embodiment is the same as the embodiment of FIG. 16 except that the panel pad 210 further includes one vertical portion 211 not connected to the horizontal portion 212 and one vertical portion 211 connected to the horizontal portion 212. A detailed description of same constituent elements will be omitted.

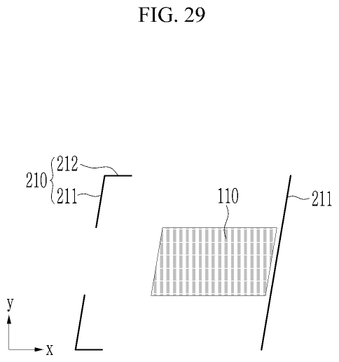

FIG. 28 illustrates a configuration in which a left side of the panel pad 210 is a vertical portion 211 not connected to the horizontal portion 212, but alternatively, as illustrated in FIG. 29, a right side of the panel pad 210 may be the vertical portion 211 not connected to the horizontal portion 212.

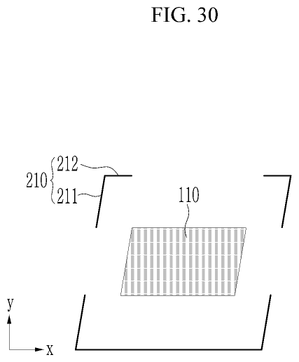

An embodiment of FIG. 30 is substantially the same as the embodiment of FIG. 16, except that the panel pad 210 further includes a horizontal portion 212 positioned at a lower end of the panel pad 210 and connected between the vertical portions 211. Accordingly, any repetitive detailed description of same constituent elements will be omitted.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel including a non-display area in which a panel pad is disposed; and
a pad portion which contacts the non-display area of the display panel,
wherein the pad portion includes an alignment mark overlapping the panel pad,
the panel pad includes a first vertical portion and a second vertical portion spaced apart from each other in a first direction,
a first horizontal portion connected to the first vertical portion, and
a second horizontal portion connected to the second vertical portion, and
the first horizontal portion and the second horizontal portion are spaced apart from each other in a second direction crossing the first direction.

2. The display device of claim 1, wherein
a distance between the first vertical portion and the second vertical portion in the first direction is equal to or longer than a length of the alignment mark in the first direction.

3. The display device of claim 1, wherein
a distance between the first horizontal portion and the second horizontal portion in the second direction is equal to or shorter than a length of the alignment mark in the second direction.

4. The display device of claim 1, wherein
the first horizontal portion and the second horizontal portion extend from the first vertical portion and the second vertical portion, respectively, in a direction away from the alignment mark.

5. The display device of claim 1, wherein
the first horizontal portion and the second horizontal portion extend from the first vertical portion and the second vertical portion, respectively, in a direction closer to the alignment mark.

6. The display device of claim 1, wherein
at least one selected from the first vertical portion and the second vertical portion includes parts spaced apart from each other in the first direction.

7. The display device of claim 1, wherein
the first vertical portion is connected to a part of the first horizontal portion other than an end part of the first horizontal portion.

8. The display device of claim 1, wherein
a corner of the alignment mark corresponding to the first horizontal portion of the panel pad includes a portion which does not overlap the first horizontal portion of the panel pad.

9. The display device of claim 1, wherein
the panel pad is not connected to a wire disposed in the display panel.

10. The display device of claim 1, wherein
an angle between the first vertical portion and the first horizontal portion is less than 90 degrees.

11. The display device of claim 1, further comprising
a third horizontal portion connected between the first vertical portion and the second vertical portion.

12. A display device comprising:
a display panel including a non-display area in which a panel pad is disposed; and
a pad portion which contacts the non-display area of the display panel,
wherein the pad portion includes an alignment mark overlapping the panel pad, and
the panel pad includes a first vertical portion and a second vertical portion spaced apart from each other in a first direction.

13. The display device of claim 12, further comprising
a first horizontal portion positioned between the first vertical portion and the second vertical portion,
wherein the first horizontal portion is not connected to at least one selected from the first vertical portion and the second vertical portion.

14. The display device of claim 12, further comprising
a second horizontal portion connected to the first vertical portion,
wherein the second horizontal portion is not connected to the second vertical portion.

15. The display device of claim 14, wherein
the second horizontal portion extends from the first vertical portion in a direction closer to the alignment mark.

16. The display device of claim 14, wherein
the second horizontal portion extends from the first vertical portion in a direction away from the alignment mark.

17. The display device of claim 14, wherein
the first vertical portion is connected to a part of the second horizontal portion other than an end part of the second horizontal portion.

18. The display device of claim 12, wherein
at least one selected from the first vertical portion and the second vertical portion includes parts which are spaced apart from each other in a second direction crossing the first direction.

19. The display device of claim 12, further comprising
a third horizontal portion connected between the first vertical portion and the second vertical portion.

20. The display device of claim 12, wherein
an angle between the first vertical portion and a horizontal side of the alignment mark is less than 90 degrees.
